(19) United States
(12) Patent Application Publication
(10) Pub. No.: US 2025/0087971 A1
(43) Pub. Date: Mar. 13, 2025

(54) NITRIDE LIGHT-EMITTING ELEMENT

(71) Applicant: Panasonic Holdings Corporation, Osaka (JP)

(72) Inventors: AKIO UETA, Shizuoka (JP); TAKASHI KANO, Shiga (JP); HIROSHI OHNO, Osaka (JP); AKIHIKO ISHIBASHI, Osaka (JP)

(21) Appl. No.: 18/960,964

(22) Filed: Nov. 26, 2024

Related U.S. Application Data
(63) Continuation of application No. PCT/JP2023/012214, filed on Mar. 27, 2023.

(30) Foreign Application Priority Data
May 31, 2022 (JP) 2022-088788

(51) Int. Cl. H01S 5/30; H01S 5/22; H01S 5/323

(52) U.S. Cl. CPC H01S 5/3013; H01S 5/221; H01S 5/3054; H01S 5/32341

(57) ABSTRACT

A nitride light-emitting element includes: a GaN substrate; an n-type semiconductor layer including an n-type nitride-based semiconductor, the n-type semiconductor layer being disposed on the GaN substrate; a p-type semiconductor layer including a p-type nitride-based semiconductor; an active layer including a nitride-based semiconductor containing Ga or In, the active layer being disposed between the n-type semiconductor layer and the p-type semiconductor layer; and a p-type electron barrier layer including Al, the p-type electron barrier layer being disposed between the active layer and the p-type semiconductor layer. The p-type electron barrier layer shows a composition distribution in which a position in a depth direction of the p-type electron barrier layer is taken as a horizontal axis, and a proportion of an Al element in a total amount of group III elements at each position is taken as a vertical axis. The composition distribution has maximum value A₁. The maximum value A₁ is 46 mol % or more. The composition distribution has a width La of a region including the maximum value A₁ in which the proportion of the Al element is continuously 0.9 times or more maximum value A₁. A ratio of the width La to a thickness Lm of the p-type electron barrier layer is 0.2 or less.

### TECHNICAL FIELD

The present invention relates to a nitride light-emitting element.

### BACKGROUND ART

Group III nitride crystals are used in optical semiconductor devices such as semiconductor lasers (LD) and light emitting diodes (LED) because they can cover a wide band gap by changing the composition of group III elements (Ga, Al, In). Moreover, group III nitride crystals have a high dielectric breakdown field of 3.3 MV/cm⁻³ (GaN), and are therefore widely used in electronic devices and the like for high frequency and high power applications. In particular, a semiconductor laser operated in a blue region is expected to be used for a display, a processing machine, a headlight, and the like, and improvement in performance of the semiconductor laser is desired. Furthermore, in particular, in order to realize long-term operation of several thousand hours or more, it is important to suppress heat generation of the semiconductor laser itself, and it is necessary to realize low power consumption driving.

In order to realize low power consumption of a nitride semiconductor laser, suppressing a leakage current is one of important points. The leakage current is a phenomenon in which electrons injected from the n-type clad layer into the active layer thermally overflow from the active layer to the p-type clad layer side. PTLs 1, 2, and 3 show a structure in which an n-type clad layer, an active layer, an electron barrier layer, and a p-type clad layer are stacked in this order on a GaN substrate. The electron barrier layer has band gap energy higher than that of the p-type clad layer in order to suppress a leakage current from the active layer.

In the above-mentioned PTLs, as the electron barrier layer, an AlGaN layer is used in which the maximum value of a ratio of the Al element to a total amount of the Al element and the Ga element (Hereinafter, also referred to as “Al composition”) is 20 mol % to 35 mol %. Furthermore, PTLs 2 and 3 disclose that the Al composition of the electron barrier layer itself affects an operating voltage. For example, in PTL 2, electron barrier layer 107 having an Al composition as illustrated in FIG. 12 is assumed in order to reduce a driving voltage. Electron barrier layer 107 has region X1 in which the Al composition is inclined (increased) on the active layer side and region X3 in which the Al composition is inclined (decreased) on the p-type clad layer side. PTL 2 has studied, by calculation, the operating voltage of the nitride laser when a film thickness of region X1 and a film thickness of region X3 are changed.

FIG. 13 illustrates a calculation result of the operating voltage in a case where the film thickness of region X1 is changed, which is disclosed in PTL 2, and FIG. 14 illustrates a calculation result of the operating voltage in a case where the film thickness of region X3 is changed. From the calculation result illustrated in FIG. 13, it can be seen that a gentle change in Al composition is preferable on the active layer side of the electron barrier layer. That is, it is disclosed that long X1 region can reduce the change in potential due to the piezoelectric effect at the interface and reduce the operating voltage. Based on the calculation result, the operating voltage can be reduced by setting a width of region X1 where the Al composition changes to 5 nm to 10 nm or more.

Furthermore, from the calculation result illustrated in FIG. 14, it can be seen that a steep change in Al composition is preferable on the p-type clad layer side of the electron barrier layer. That is, it is disclosed that region X3 having a steep Al composition change can reduce the energy barrier against holes and reduce a voltage operation. Based on the calculation result, it can be said that it is important for the low driving voltage that a width of region X3 where the Al composition changes satisfies 5 nm or less, that is, a rate of change in the Al composition (hereinafter also referred to as “slope”) in region X3 is 7 mol %/nm or more. Moreover, by setting the width of region X3 to 3 nm or less, that is, by setting the change rate (slope) of the Al composition to 11.6 mol %/nm or more, it can be said that a further voltage reduction effect can be obtained.

### CITATION LIST

### Patent Literature

PTL 1: Unexamined Japanese Patent Publication No. 2018-200928
PTL 2: Japanese Patent No. 6831375
PTL 3: Japanese Patent No. 6754918

### SUMMARY OF THE INVENTION

A nitride light-emitting element according to one aspect of the present disclosure includes: a GaN substrate; an n-type semiconductor layer including an n-type nitride-based semiconductor, the n-type semiconductor layer being disposed on the GaN substrate; a p-type semiconductor layer including a p-type nitride-based semiconductor; an active layer including a nitride-based semiconductor containing Ga or In, the active layer being disposed between the n-type semiconductor layer and the p-type semiconductor layer; and a p-type electron barrier layer including Al, the p-type electron barrier layer being disposed between the active layer and the p-type semiconductor layer, in which the p-type electron barrier layer shows a composition distribution in which a position in a depth direction of the p-type electron barrier layer is taken as a horizontal axis, and a proportion of an Al element in a total amount of group III elements at each position is taken as a vertical axis, the composition distribution has maximum value A₁, the maximum value A₁ is 46 mol % or more, the composition distribution has a width La of a region including the maximum value A₁ in which the proportion of the Al element is continuously 0.9 times or more the maximum value A₁, and a ration of the width La to a thickness Lm of the p-type electron barrier layer is 0.2 or less.

### BRIEF DESCRIPTION OF THE DRAWINGS

FIG. 1 is a schematic diagram of a nitride semiconductor laser according to a first exemplary embodiment of the present disclosure.

FIG. 2 is a finished diagram of an ideal Al composition and film thickness in a growth sequence in an MOCVD method of an electron barrier layer according to the first exemplary embodiment of the present disclosure.

FIG. 3 is a diagram illustrating an atom probe analysis result of an Al composition in a stacking direction of the electron barrier layer according to the first exemplary embodiment of the present disclosure.

FIG. 4 is a schematic diagram illustrating an Al diffusion mechanism according to the first exemplary embodiment of the present disclosure.

FIG. 5 is an Al composition distribution of the electron barrier layer according to the first exemplary embodiment of the present disclosure.

FIG. 6 is a finished diagram of an ideal Al composition and film thickness in a growth sequence in an MOCVD method of an electron barrier layer according to a second exemplary embodiment of the present disclosure.

FIG. 7 is an atom probe analysis result of an Al composition in a stacking direction of the electron barrier layer according to the second exemplary embodiment of the present disclosure.

FIG. 8 is an Al composition distribution of the electron barrier layer according to the second exemplary embodiment of the present disclosure.

FIG. 9 is a correlation diagram between an AIN film thickness and a slope of the Al composition on a p-type semiconductor layer side of the electron barrier layer in the present disclosure.

FIG. 10 is a crystal structure diagram illustrating calculation of average binding energy of the electron barrier layer according to the second exemplary embodiment of the present disclosure.

FIG. 11 is a correlation diagram between the average binding energy of the electron barrier layer and the slope of the Al composition on the p-type semiconductor layer side in the present disclosure.

FIG. 12 is a composition distribution (assumed diagram) of Al in an electron barrier layer in PTL 2.

FIG. 13 is a diagram illustrating a relationship between a film thickness of region X1 where an Al composition is inclined and an operating voltage of a laser in FIG. 12.

FIG. 14 is a diagram illustrating a relationship between a film thickness of region X3 where the Al composition is inclined and the operating voltage of the laser in FIG. 12.

FIG. 15 is a finished diagram of an ideal Al composition and film thickness in a growth sequence of an electron barrier layer of a conventional example in an MOCVD method.

FIG. 16 is a diagram illustrating an atom probe analysis result of an Al composition in a stacking direction of the electron barrier layer of the conventional example.

FIG. 17 is a schematic diagram illustrating an Al diffusion mechanism in the conventional example.

### DESCRIPTION OF EMBODIMENT

In an AlGaN layer (for example, an Al_{0.35}Ga_{0.65}N layer) as disclosed in PTLs 2 and 3, it is difficult to set the slope of the Al composition of region X3 to 7 mol %/nm or more. As described above, region X3 is a region in which the Al composition changes on the p-type clad layer side of the electron barrier layer. This is considered to be because Al in the electron barrier layer has diffused into an upper layer during the growth of the p-type clad layer. Therefore, a trial production examination was conducted by changing the growth conditions of the p-type clad layer, such as changing the growth temperature of the p-type clad layer and the time (interruption time) from the formation of an Al_{0.35}Ga_{0.65}N layer to the start of the p-type clad layer growth. However, almost the same slope of the Al composition was obtained under any condition, and a region having a steep slope of 7 mol %/nm or more could not be obtained.

As a result of intensive studies by the present inventors, it has been found that a region in which the Al composition changes with a steep slope is obtained in the electron barrier layer by controlling the binding energy of the crystal of several atomic layers on the p-type semiconductor layer side of the electron barrier layer.

An object of the present disclosure is to provide a nitride light-emitting element that has an electron barrier layer with a steep slope of an Al composition on a p-type semiconductor layer side and is capable of a low-voltage operation.

### Conventional Example

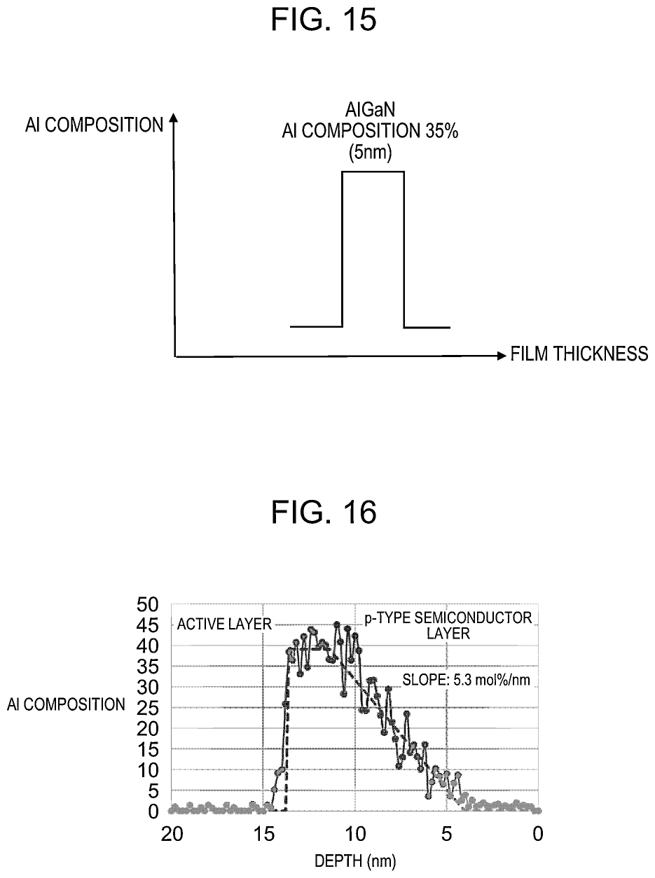

First, the Al_{0.35}Ga_{0.65}N layer described in PTL 2 will be described. FIG. 15 illustrates a finished diagram of an ideal Al composition and film thickness in a growth sequence in the case of producing the Al_{0.35}Ga_{0.65}N layer described in PTL 2. FIG. 16 is a diagram illustrating an analysis result by an atom probe evaluation, that is, a relationship between a depth direction and the Al composition at the corresponding position in a case where the Al_{0.35}Ga_{0.65}N layer is produced on the basis of the design illustrated in FIG. 15.

In the atom probe evaluation method, a measurement sample is processed into a sharp needle-shaped sample having a tip diameter of about 100 nm, and a positive voltage of about 10 kV is applied, so that a high electric field is generated at the most distal end of the sample, and an electric field evaporation phenomenon is generated. Ions electrovaporized from the sample are evaluated by a two-dimensional detector to identify ion species. Then, the individually detected ions are continuously detected and reconstructed in the depth direction to obtain a three-dimensional atomic distribution.

In the Al_{0.35}Ga_{0.65}N layer to be produced, as illustrated in FIG. 15, it is desirable that the Al composition rapidly changes according to the growth sequence, that is, an Al composition distribution with the position in the depth direction of the electron barrier layer as the horizontal axis and a ratio of the Al element to a total amount of the group III elements at each position as the vertical axis has a rectangular shape. However, actually, as illustrated in FIG. 16, it can be seen that Al is also present in a region (p-type semiconductor layer) where supply of Al is stopped, and Al is diffused into the upper growth layer (p-type semiconductor layer). Furthermore, a slope of the obtained Al composition was 5.3 mol %/nm. That is, in the technique disclosed in PTL 2, the effect of reducing the operating voltage of the nitride light-emitting element cannot be sufficiently obtained, and there is a concern about an increase in voltage. On the other hand, on the active layer side of the electron barrier layer, the slope of the Al composition is as steep as 30 mol %/nm. However, in this case, it is considered that the gentle Al composition change region disclosed in PTL 2 can be easily formed by changing the growth sequence.

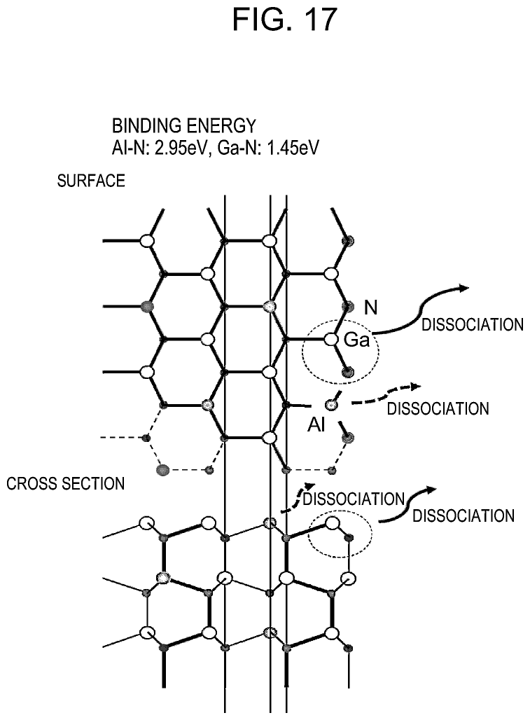

Next, a mechanism in which Al diffusion occurs on the p-type semiconductor layer side as illustrated in FIG. 16 in a case where the Al_{0.35}Ga_{0.65}N electron barrier layer is produced will be described. FIG. 17 is an explanatory diagram of a mechanism using a crystal lattice diagram of an interface (surface) of the Al_{0.35}Ga_{0.65}N electron barrier layer with the p-type semiconductor layer and a cross section in the vicinity of the p-type semiconductor layer. As illustrated in the cross-sectional view of FIG. 17, the nitride crystal has a hexagonal crystal structure in which a group III atom and a nitrogen atom are repeatedly stacked. Here, the group III atoms are Al atoms and Ga atoms, and these atoms are randomly arranged in a ratio (that is, 35% are Al atoms, and the remaining 65% are Ga atoms.) corresponding to the composition.

As described above, in a case where Al atoms in the electron barrier layer diffuse into the upper p-type semiconductor layer region, the Al atoms need to break Al-N bonds to be free. The binding energy between the Al atom and the nitrogen atom is 2.95 eV, and the binding energy between the Ga atom and the nitrogen atom is 1.45 eV. Considering these two binding energies, the Ga—N bond is more likely to be broken. Therefore, in Al_{0.35}Ga_{0.65}N, it is considered that Ga atoms existing near Al atoms first break the bonds and become free. In a case where Ga atoms existing in the vicinity become free, the nitrogen atoms one level below to which the Al atoms and the (free) Ga atoms have been commonly bonded are also unstable because the bonds with the Ga atoms are broken. As a result, the unstable nitrogen atoms are also easily desorbed. Then, when the unstable N atoms bonded to the Al atoms are removed by desorption, each of the Al atoms themselves also loses one of the bonds, and the energy required to dissociate the bond decreases. That is, in a state of being bonded to the lower nitrogen atom with three bonds, the bond dissociation energy of Al of 2.95 eV×3=8.85 eV decreases to 2.95 eV×2=5.9 eV because one nitrogen atom is removed. Therefore, the Al atom itself becomes unstable and tends to be free. Note that, in the case of Al_{0.35}Ga_{0.65}N, 65% of the group III atoms are Ga atoms, and thus there is a high possibility that Ga atoms exist in atoms adjacent to the Al atoms (bonded to a common nitrogen atom). Therefore, the Ga—N bond around the Al atom is likely to collapse, and the Al atom is likely to be free. As a result, it is considered that Al is easily diffused into the upper p-type semiconductor layer.

Exemplary embodiments of the present invention will be described below with reference to drawings.

### FIRST EXEMPLARY EMBODIMENT

### Configuration of Nitride Light-Emitting Element

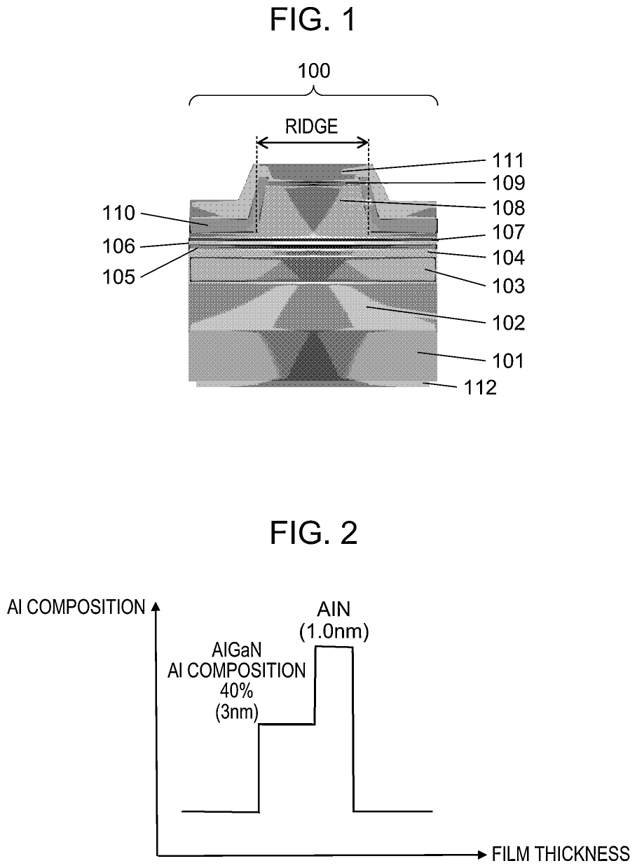

FIG. 1 is a schematic diagram of a cross section perpendicular to a resonance direction of nitride light-emitting element (Hereinafter, also referred to as “nitride semiconductor laser”.) 100 in a first exemplary embodiment of the present invention.

In nitride semiconductor laser 100, n-type AlGaN clad layer 102, n-type GaN clad layer 103, n-side InGaN guide layer 104, InGaN/InGaN DQWs active layer 105, p-side InGaN guide layer 106, electron barrier layer 107 including p-type AlGaN, p-type AlGaN/GaN superlattice clad layer 108, and p-type GaN contact layer 109 are sequentially stacked on GaN substrate 101. Furthermore, a ridge structure is formed in p-type AlGaN/GaN superlattice clad layer 108 and p-type GaN contact layer 109 by photolithography and etching. Moreover, current block region 110 including SiO₂ is provided on a ridge sidewall. Moreover, p-electrode 111 and n-electrode 112 are formed on p-type GaN contact layer 109 on top of the ridge and on GaN substrate 101, respectively. Note that, in the present exemplary embodiment, n-type AlGaN clad layer 102 and n-type GaN clad layer 103 correspond to an n-type semiconductor layer including an n-type nitride-based semiconductor. Furthermore, InGaN/InGaN DQWs active layer 105 corresponds to an active layer including a nitride-based semiconductor containing Ga or In. Moreover, p-type AlGaN/GaN superlattice clad layer 108 and p-type GaN contact layer 109 correspond to a p-type semiconductor layer including a p-type nitride-based semiconductor.

### Method of Manufacturing Nitride Light-Emitting Element

A method for manufacturing nitride semiconductor laser 100 having the above structure will be specifically described.

Nitride semiconductor laser 100 having the structure of FIG. 1 is formed by epitaxially growing each nitride layer on GaN substrate 101 using a metal organic chemical vapor deposition (MOCVD) method. As a group III raw material, trimethylgallium (TMG), trimethylindium (TMI), and trimethylaluminum (TMA) are used. As a group V raw material, ammonia (NH₃) gas is used. As a dopant, monosilane (SiH₄) and cyclopentadienyl magnesium (CP₂Mg) are used, and an n-type layer and a p-type layer are obtained from these materials, respectively. Furthermore, hydrogen or nitrogen is used as a carrier gas when the MOCVD method is performed.

First, GaN substrate 101 introduced into an MOCVD furnace before epitaxial growth is thermally cleaned at 1100° C. in a hydrogen and NH₃ atmosphere. By the thermal cleaning, carbon-based dirt adhering to a surface of the substrate and an oxide film on the surface of the substrate are removed.

Thereafter, the temperature is raised to 1130° C., and n-type AlGaN clad layer 102 and n-type GaN clad layer 103 are sequentially grown by supplying respective source gases together with the carrier gas. A film thickness of n-type AlGaN clad layer 102 is 1.5 μm, and an Al composition thereof is 2.6%. On the other hand, a film thickness of n-type GaN clad layer 103 is 250 nm. When these layers are formed, SiH₄ is supplied during growth in order to achieve n-type conduction. As a result, Si is doped into the film at 1.0×10¹⁸ cm⁻³. Next, the growth temperature is lowered to 840° C., and n-side InGaN guide layer 104 having an In composition of 2.6% is grown to 180 nm.

Subsequently, InGaN/InGaN DQWs active layer 105 is grown at the same temperature. InGaN/InGaN DQWs active layer 105 has a structure in which two InGaN layer well layers (thickness 2.8 nm, In composition 18%) are sandwiched between InGaN barrier layers (thickness 7 nm, In composition 3.4%).

p-side InGaN guide layer 106 (film thickness 150 nm, In composition 2.6%) is grown on InGaN/InGaN DQWs active layer 105. Next, the growth temperature is raised to 985° C., and p-type electron barrier layer 107 including AlGaN having a thickness of 3 nm and an Al composition of 40% and AlN having a thickness of 1 nm is formed. Moreover, p-type AlGaN/GaN superlattice clad layer 108 having a film thickness of 660 nm is formed by stacking a pair of an AlGaN layer having a thickness of 1.85 nm and an Al composition of 5.2% and a GaN layer having a thickness of 1.85 nm. Next, p-type GaN contact layer 109 having a film thickness of 60 nm is formed.

p-type electron barrier layer 107, p-type AlGaN/GaN superlattice clad layer 108, and p-type GaN contact layer 109 dope Mg in the film by supplying CP₂Mg during growth to obtain p-type conduction. p-type electron barrier layer 107, p-type AlGaN/GaN superlattice clad layer 108, and p-type GaN contact layer 109 contain Mg of 1.0×10¹⁹ cm⁻³, 2.0×10¹⁸ cm⁻³ to 1.0×10¹⁹ cm⁻³, and 2.0×10²⁰ cm⁻³, respectively.

Furthermore, p-electrode 111 and n-electrode 112 include Pd, Pt, and Au, and Ti, Pt, and Au, respectively. In the present first exemplary embodiment, in order to obtain an oscillation wavelength of 450 nm, the InGaN layer having a thickness of 2.8 nm and an In composition of 18% is used as a well layer of InGaN/InGaN DQWs active layer 105, but the In composition and the thickness may be adjusted in accordance with the oscillation wavelength of 420 nm to 460 nm. Furthermore, although the (average) Al composition of n-type AlGaN clad layer 102 and p-type AlGaN/GaN superlattice clad layer 108 is 2.6%, in order to confine light perpendicularly to InGaN/InGaN DQWs active layer 105, the Al composition and the film thickness may be adjusted within a range where the effective refractive index of the active layer is also small and the Al composition is 2.5% to 5%.

### p-Type Electron Barrier Layer

p-type electron barrier layer 107 in the present first exemplary embodiment will be described. FIG. 2 is a finished diagram of an ideal Al composition and film thickness in a growth sequence in an MOCVD method of p-type electron barrier layer 107 in the present first exemplary embodiment. FIG. 3 is a diagram illustrating an analysis result of the Al composition in a stacking direction by an atom probe, that is, a relationship between a depth direction and the Al composition at the corresponding position in a case where p-type electron barrier layer 107 is formed on the basis of the design illustrated in FIG. 2.

As described above, p-type electron barrier layer 107 includes Al_{0.4}Ga_{0.6}N having a thickness of 3 nm and AlN having a thickness of 1 nm. In p-type electron barrier layer 107 obtained by such a design, as illustrated in FIG. 3, the Al composition has a maximum value of 60 mol % or less (55 mol % or less in FIG. 3) on a p-type semiconductor layer side. In p-type electron barrier layer 107, Al diffusion to the p-type semiconductor layer side where an increase in operating voltage is concerned is greatly suppressed as compared with FIG. 16 that is a conventional structure. A slope of the Al composition in a region adjacent to the p-type semiconductor layer estimated from FIG. 3 is 31.1 mol %/nm. That is, the slope is greatly improved as compared with the conventional structure. Moreover, as compared with the slope of the Al composition effective for voltage reduction of 7 mol %/nm and the more preferable slope of 11.6 mol %/nm described in PTL 2, the value is sufficiently large and has a steepness close to an ideal. The slope of the Al composition may be 7 mol %/nm or more and 31.1 mol %/nm or less.

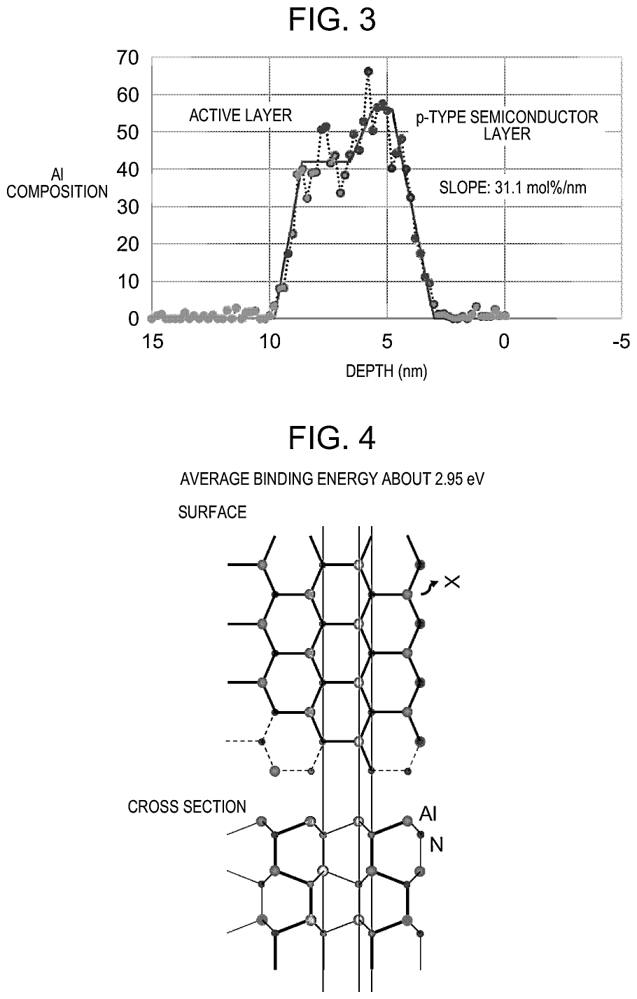

As a factor of suppressing the Al diffusion toward the p-type semiconductor layer side in p-type electron barrier layer 107 of the present first exemplary embodiment, the following mechanism is considered. FIG. 4 is an explanatory diagram of the mechanism using a crystal lattice diagram of a surface of p-type electron barrier layer 107 on the p-type AlGaN/GaN superlattice clad layer 108 (p-type semiconductor layer) side and a cross section of p-type electron barrier layer 107 in the vicinity of p-type AlGaN/GaN superlattice clad layer 108 (p-type semiconductor layer) in the present first exemplary embodiment. In the present first exemplary embodiment, the p-type AlGaN/GaN superlattice clad layer 108 side of p-type electron barrier layer 107 is terminated with an AlN crystal having a thickness of 1 nm. The thickness of 1 nm corresponds to four atomic layers of AlN crystals, and as illustrated in the cross-sectional view of FIG. 4, the group III atoms on a surface side (p-type AlGaN/GaN superlattice clad layer 108 side) are composed only of Al atoms. The binding energy between the Al atom and the nitrogen atom is 2.95 eV, and the binding energy on the surface of p-type electron barrier layer 107 is equivalent to the binding energy of an Al—N bond, and has strong binding energy. Therefore, as described above (FIG. 17), diffusion of Al atoms resulting from cleavage of a Ga—N bond hardly occurs. That is, in the present first exemplary embodiment, in order to make the Al atoms in the vicinity of the surface free, it is necessary to cut all the bonds with the three nitrogen atoms bonded to a lower portion. Therefore, it is considered that Al diffusion hardly occurs. By introducing p-type electron barrier layer 107 containing the AlN crystals on the p-type semiconductor layer side as described above, Al diffusion to the p-type semiconductor layer side can be suppressed.

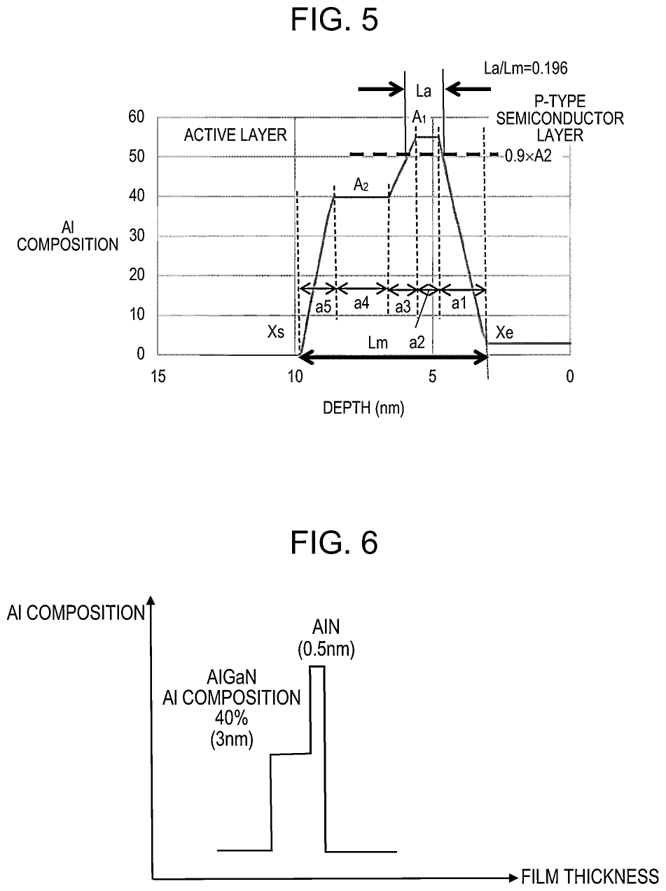

FIG. 5 illustrates a diagram (composition distribution with a position in the depth direction of the electron barrier layer as a horizontal axis and a ratio of the Al element to a total amount of the group III elements at each position as a vertical axis) when an atom probe analysis result of p-type electron barrier layer 107 in the present first exemplary embodiment is linearly shown. Here, thickness Lm of p-type electron barrier layer 107 can be considered as from position Xs to position Xe. Position Xs is a position where the Al composition rises on an active layer 105 side. Position Xe is a position where the Al composition matches the Al composition of clad layer 108 on the clad layer 108 side. Thickness Lm in the present first exemplary embodiment is 6.8 nm.

Furthermore, the composition distribution includes first region a1, second region a2, third region a3, fourth region a4, and fifth region a5 from clad layer (p-type semiconductor layer) 108 toward active layer 105. First region a1 is a region in which the proportion of the Al element changes at a first change rate. Second region a2 is a region where the proportion of the Al element changes at a second change rate. Third region a3 is a region where the proportion of the Al element changes at a third change rate. Fourth region a4 is a region where the proportion of the Al element changes at a fourth change rate. Fifth region a5 is a region where the proportion of the Al element changes at a fifth change rate. Note that the second change rate is different from the first change rate and the third change rate, and the fourth change rate is at least different from the third change rate and the fifth change rate.

In the composition distribution, second region a2 and fourth region a4 are substantially flat. Maximum value A₁ of the Al composition distribution exists in the second region. As described above, maximum value A₁ is 55 mol %. Furthermore, a width of second region a2 is 1.0 nm. Moreover, the composition distribution has width La of a region including maximum value A₁ in which the ratio of the Al element is continuously 0.9 times or more maximum value A₁. Width La is 1.3 nm. Then, the ratio of width La to thickness Lm of p-type electron barrier layer 107, that is, La/Lm is 0.196. On the other hand, when the maximum value of fourth region a4 is defined as second maximum value A₂, second maximum value A₂ is 40 mol %. The width of second region a2 may be 1.0 nm or less.

In p-type electron barrier layer 107 of the present first exemplary embodiment, a region from start position Xs on the active layer side in p-type electron barrier layer 107 to second maximum value A₂, that is, fifth region a5 and fourth region a4 mainly have a function of suppressing overflow of electrons injected into active layer 105. Therefore, when thickness Lm of p-type electron barrier layer 107 itself is too thin, the function as an electron barrier layer is deteriorated. Furthermore, since second region a2 including maximum value A₁ has a high Al concentration, it is preferable that second region a2 is thin for a low-voltage operation of the nitride laser. Therefore, the width of the region having a high Al concentration, that is, above-described width La is preferably 1.5 nm or less, and the above-described La/Lm is preferably 0.2 or less. In order to further utilize the function as the electron barrier layer, the Al composition at second maximum value A₂ is desirably 30 mol % or more and 40 mol % or less, and more preferably 35 mol % or more and 40 mol % or less. With this configuration, the interface steepness of the electron barrier layer on the second conductive side first semiconductor layer side can be greatly improved, and the operating voltage of the nitride light-emitting element can be reduced. The ratio of second maximum value A₂ to maximum value A₁ may be 0.55 or more and 0.89 or less.

### Second Exemplary Embodiment

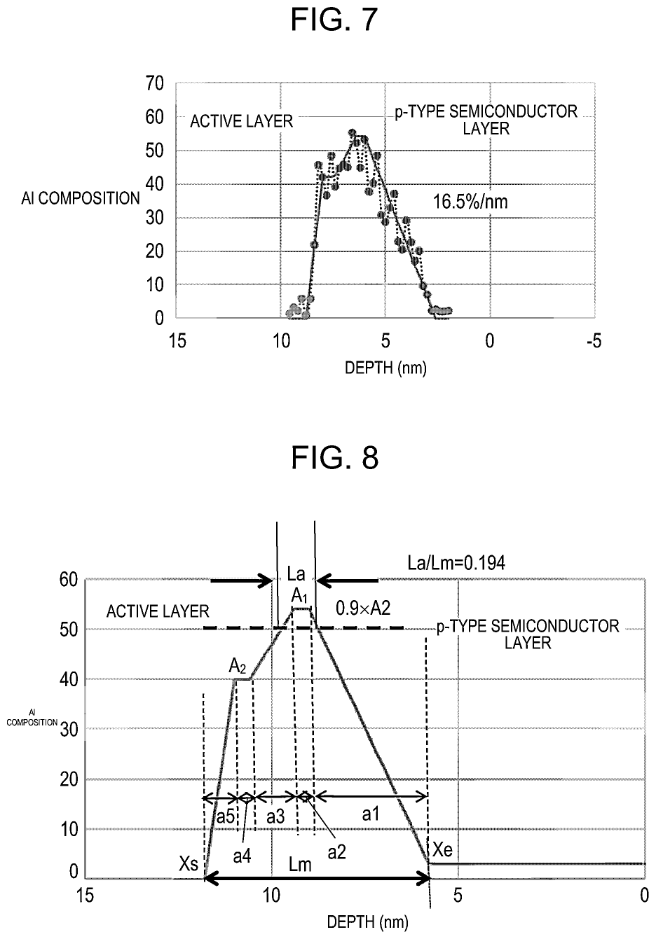

The structure of a nitride semiconductor laser according to a second exemplary embodiment is substantially the same as that of the first exemplary embodiment except for the configuration of p-type electron barrier layer 107. FIG. 6 is a finished diagram of an ideal Al composition and film thickness in a growth sequence in an MOCVD method of p-type electron barrier layer 107 in the second exemplary embodiment. FIG. 7 is a diagram illustrating an atom probe analysis result of the Al composition in the stacking direction, that is, a relationship between the depth direction and the Al composition at the corresponding position in a case where p-type electron barrier layer 107 is produced on the basis of the design illustrated in FIG. 6.

In the present second exemplary embodiment, as illustrated in FIG. 6, p-type electron barrier layer 107 includes Al_{0.4}Ga_{0.6}N having a thickness of 3 nm and AlN having a thickness of 0.5 nm. In p-type electron barrier layer 107 obtained by such a design, as illustrated in FIG. 7, the Al composition has a maximum value of 60 mol % or less (here, 54 mol %) on the p-type AlGaN/GaN superlattice clad layer (p-type semiconductor layer) 108 side. The slope of the Al composition in the region adjacent to the p-type semiconductor layer estimated from FIG. 7 is 16.5%/nm. That is, it has a steep slope close to an ideal. Therefore, also in the present second exemplary embodiment, the operating voltage of the nitride semiconductor laser can be reduced.

FIG. 8 illustrates a diagram (composition distribution with a position in the depth direction of the electron barrier layer as a horizontal axis and a ratio of the Al element to a total amount of the group III elements at each position as a vertical axis) when an atom probe analysis result of p-type electron barrier layer 107 in the present second exemplary embodiment is linearly shown. Also in the present second exemplary embodiment, similarly to FIG. 5, thickness Lm of p-type electron barrier layer 107 can be considered as from position Xs to position Xe. Thickness Lm of p-type electron barrier layer 107 is 6.2 nm.

Furthermore, the composition distribution of the present second exemplary embodiment also includes first region a1, second region a2, third region a3, fourth region a4, and fifth region a5 from clad layer (p-type semiconductor layer) 108 toward active layer 105. First region a1 is a region in which the proportion of the Al element changes at a first change rate. Second region a2 is a region where the proportion of the Al element changes at a second change rate. Third region a3 is a region where the proportion of the Al element changes at a third change rate. Fourth region a4 is a region where the proportion of the Al element changes at a fourth change rate. Fifth region a5 is a region where the proportion of the Al element changes at a fifth change rate. The second change rate is at least different from the first change rate and the third change rate, and the fourth rate of change is at least different from the third rate change and the fifth change rate.

Also in the composition distribution, second region a2 and fourth region a4 are substantially flat. Maximum value A₁ of the Al composition distribution exists in the second region. As described above, maximum value A₁ is 54 mol %. Furthermore, a width of second region a2 is 0.4 nm. Moreover, in the present second exemplary embodiment, width La of a region including maximum value A₁, in which the ratio of the Al element is continuously 0.9 times or more maximum value A₁, is 1.2 nm. Then, the ratio of width La to thickness Lm of p-type electron barrier layer 107, that is, La/Lm is 0.194. That is, the above preferable range (La/Lm≤0.20) is satisfied. Moreover, when the maximum value of fourth region a4 is defined as second maximum value A₂, second maximum value A₂ is 40 mol %.

### AlN Film Thickness of Electron Barrier Layer

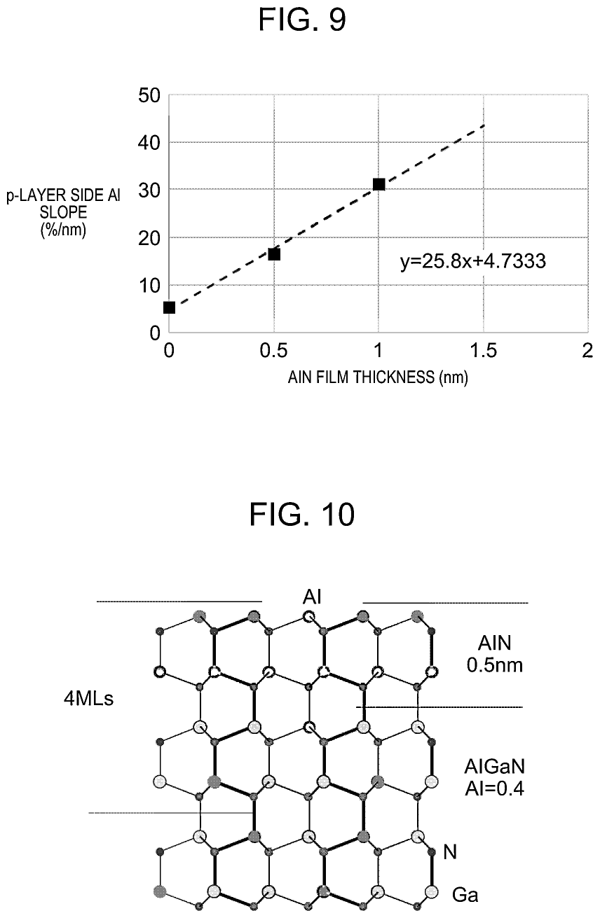

In the first and second exemplary embodiments described above, the thin film AlN of 1.0 nm or less is grown on the p-type AlGaN/GaN superlattice clad layer 108 side of p-type electron barrier layer 107, so that Al diffusion to the p-type semiconductor layer side can be suppressed, and the slope of the Al composition can be set to 7 mol %/nm or more. FIG. 9 illustrates a correlation diagram between a thickness of AIN obtained in the exemplary embodiment and the conventional example and a slope of the Al composition to the p-type semiconductor layer side (p-layer-side Al slope). The slope of the Al composition toward the p-type semiconductor layer side changes according to the thickness of the AlN film, and it can be seen from FIG. 9 that the steepness of 7 mol %/nm or more can be realized by inserting AlN having a thickness of 0.09 nm or more.

### Average Binding Energy Control Of Electron Barrier Layer

It is considered that the change in the thickness of AIN changes the crystal binding energy of p-type electron barrier layer 107 on the p-type AlGaN/GaN superlattice clad layer 108 side to suppress the diffusion of Al. Therefore, the diffusion of Al of p-type electron barrier layer 107 into the p-type AlGaN/GaN superlattice clad layer (p-type semiconductor layer) 108 side can be expressed by a diffusion formula using the average binding energy in the crystal on the p-type AlGaN/GaN superlattice clad layer 108 side of p-type electron barrier layer 107 as the activation energy. Therefore, fitting was performed using Formula (1).

$$\begin{matrix}[ Mathematical formula 1 ] & \\ {L}_{O F S} = \sqrt{{D}_{A l} exp ( \frac{- {E}_{O F S}}{K T} ) \times t} & ( 1 )\end{matrix}$$

Here, L_{OFS} represents a diffusion length of Al, and is a value inversely proportional to the slope of the Al composition. D_{A1} is a diffusion coefficient of Al, E_{OFS} is an average binding energy of four atomic layers on the p-type AlGaN/GaN superlattice clad layer 108 side of p-type electron barrier layer 107, K is a Boltzmann constant, T is a growth temperature (985° C. in the present exemplary embodiment), and t is a growth time of p-type AlGaN/GaN superlattice clad layer 108.

FIG. 10 illustrates a crystal lattice diagram of four atomic layers on the p-type AlGaN/GaN superlattice clad layer 108 side of p-type electron barrier layer 107 of the second exemplary embodiment. The average binding energy E_{OFS} according to the second exemplary embodiment is calculated as an average binding energy of AlN for two atomic layers (0.5 nm) from the p-type AlGaN/GaN superlattice clad layer 108 side, and further Al_{0.4}Ga_{0.6}N for two atomic layers existing under the AlN. In this case, the following formula is established.

$$\{ 2.95 eV \times 2 + [ 2.95 eV \times 0.4 + 1.45 eV \times ( 1 - 0.6 ) \times 2 ] \} / 4 = 2.5 eV \qquad [ Mathematical formula 2 ]$$

In the present exemplary embodiment, since conditions other than the configuration of p-type electron barrier layer 107 are not changed, Formula (1) can be simplified and can be considered as Formula (2) described below.

$$\begin{matrix}[ Mathematical formula 3 ] & \\ Log ( {L}_{OFS}^{2} ) ∝ {E}_{O F S} & ( 2 )\end{matrix}$$

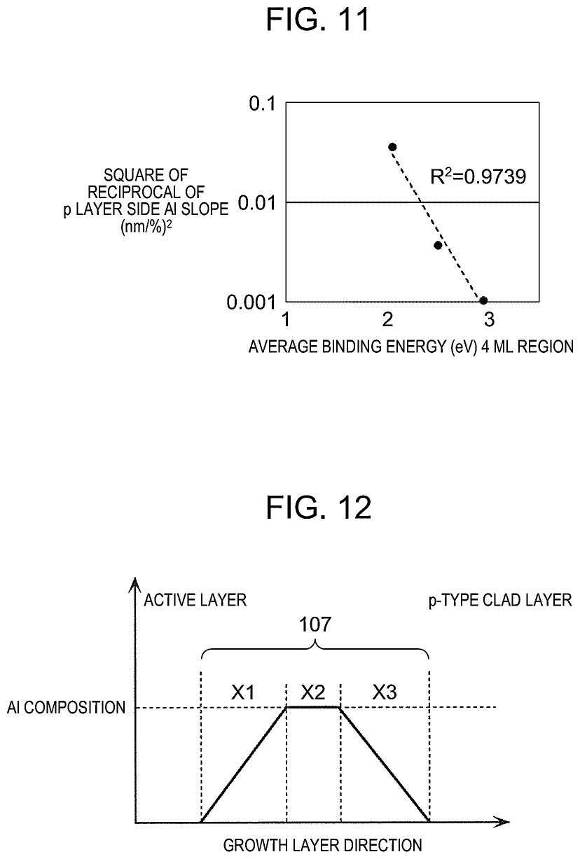

FIG. 11 illustrates a semi-logarithmic graph of the average binding energy for four atomic layers and a square value of the reciprocal of the slope of the Al composition. The good correlation in FIG. 11, in which the good correlation with the slope of the Al composition can be confirmed by using the average binding energy of four atomic layers, indicates that the slope of the Al composition can be controlled by using Formula (2) described above, that is, by controlling the average binding energy of four atomic layers on the p-type AlGaN/GaN superlattice clad layer 108 side of p-type electron barrier layer 107.

In the present first and second exemplary embodiments, AlN is used for growing p-type electron barrier layer 107, but in order to realize a slope of the Al composition of 7 mol %/nm or more, it can be seen from FIG. 11 that the growth film may be controlled so as to obtain an average binding energy of 2.14 eV. The average binding energy of 2.14 e V corresponds to the binding energy of Al_{0.46}Ga_{0.54}N. Therefore, when the nitride crystal has an average binding energy of 2.14 eV or more, that is, the maximum value of the Al composition (above-described maximum value A₁) of 46% or more, the effect of suppressing Al diffusion can be achieved. That is, when p-type electron barrier layer 107 is grown, after the AlGaN layer is grown up to second maximum value A₂ in FIGS. 5 and 6, termination of p-type electron barrier layer 107 may be performed under a condition that satisfies the following formula.

$$\begin{matrix}[ Mathematical formula 4 ] & \\ 4 \times 2.14 \leq [ ( 4 - \frac{d}{0.25} ) \times \{ 2.95 \times A + 1.45 \times ( 1 - A ) \} ] + [ \frac{d}{0.25} \times \{ 2.95 \times x + 1.45 \times ( 1 - x ) \} ] \leq 4 \times 2.95 & ( 3 )\end{matrix}$$

Here, A is the Al composition at a position of above-described second maximum value A₂, and d is a thickness of the film to be grown for termination (however, 1 nm or less). Terminating the p-type AlGaN/GaN superlattice clad layer 108 side of p-type electron barrier layer 107 under the condition that Formula (3) is satisfied makes it possible to form p-type electron barrier layer 107 capable of reducing the operating voltage of the nitride laser.

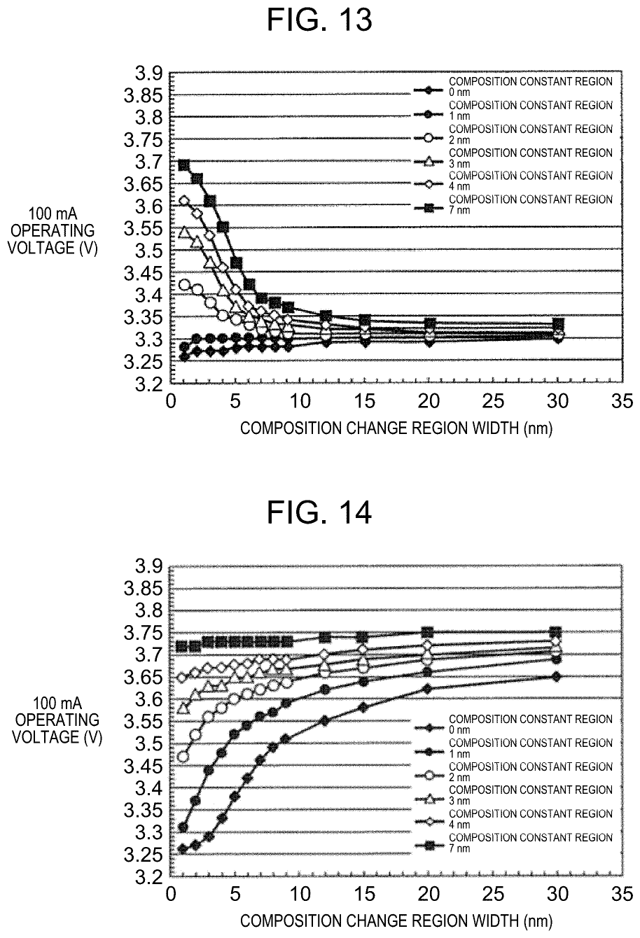

Note that, in the above-described exemplary embodiment, the Al composition inclined region of p-type electron barrier layer 107 toward the active layer 105 side is not provided, but as disclosed in PTL 2, a region where the Al composition changes may be provided as indicated by X1 in FIG. 13 for further reducing the operating voltage.

In the nitride light-emitting element of the present disclosure, the slope of the Al composition on the p-type semiconductor layer side of the electron barrier layer is steep, and a low-voltage operation is possible.

### INDUSTRIAL APPLICABILITY

In the nitride light-emitting element of the present invention, the slope of the Al composition on the p-type semiconductor layer side of the electron barrier layer is made steep, the operating voltage of the nitride light-emitting element is reduced, and low power consumption operation is enabled. Therefore, the present invention can be applied to applications such as displays, processing machines, and in-vehicle headlights.

### REFERENCE MARKS IN THE DRAWINGS

100 nitride semiconductor laser
101 GaN substrate
102 n-type AlGaN clad layer
103 n-type GaN clad layer
104 n-side InGaN guide layer
105 InGaN/InGaN DQWs active layer
106 p-side InGaN guide layer
107 electron barrier layer
108 p-type AlGaN/GaN superlattice clad layer
109 p-type GaN contact layer
110 current block region
111 p-electrode
112 n-electrode

1. A nitride light-emitting element comprising:
a GaN substrate;
an n-type semiconductor layer including an n-type nitride-based semiconductor, the n-type semiconductor layer being disposed on the GaN substrate;
a p-type semiconductor layer including a p-type nitride-based semiconductor;
an active layer including a nitride-based semiconductor containing Ga or In, the active layer being disposed between the n-type semiconductor layer and the p-type semiconductor layer; and
a p-type electron barrier layer including Al, the p-type electron barrier layer being disposed between the active layer and the p-type semiconductor layer,
wherein the p-type electron barrier layer shows a composition distribution in which a position in a depth direction of the p-type electron barrier layer is taken as a horizontal axis, and a proportion of an Al element in a total amount of group III elements at each position is taken as a vertical axis,
the composition distribution has a maximum value A₁,
the maximum value A₁ is 46 mol % or more,
the composition distribution has a width La of a region including the maximum value A₁ in which the proportion of the Al element is continuously 0.9 times or more the maximum value A₁, and
a ratio of the width La to a thickness Lm of the p-type electron barrier layer is 0.2 or less.

2. The nitride light-emitting element according to claim 1, wherein
the width La is 1.5 nm or less.

3. The nitride light-emitting element according to claim 1, wherein
the maximum value A₁ is 60 mol % or less.

4. The nitride light-emitting element according to claim 1, wherein
the composition distribution has at least a first region in which the proportion of the Al element changes at a first change rate, a second region in which the proportion of the Al element changes at a second change rate, and a third region in which the proportion of the Al element changes at a third change rate in order from the p-type semiconductor layer toward the active layer,
the second change rate is different from at least each of the first change rate and the third change rate,
the second region has the maximum value A₁, and
the second region has a width of 1.0 nm or less.

5. The nitride light-emitting element according to claim 4, wherein
the composition distribution further includes a fourth region in which the proportion of the Al element changes at a fourth change rate and a fifth region in which the proportion of the Al element changes at a fifth change rate located closer to the active layer than the third region and in order from the p-type semiconductor layer toward the active layer, and
the fourth change rate is different from at least each of the third change rate and the fifth change rate.

6. The nitride light-emitting element according to claim 5, wherein
the fourth region has a second maximum value A₂ that is 30 mol % or more and 40 mol % or less.

7. The nitride light-emitting element according to claim 6, wherein
a ratio of the second maximum value A₂ to the maximum value A₁ is 0.55 or more and 0.89 or less.

8. The nitride light-emitting element according to claim 4, wherein
the first change rate is 7.0 mol %/nm or more and 31.1 mol %/nm or less.

9. The nitride light-emitting element according to claim 1, wherein
the nitride light-emitting element includes a semiconductor laser.
